(19) United States
(12) Patent Application Publication
(10) Pub. No.: US 2016/0351465 A1
(43) Pub. Date: Dec. 1, 2016

(54) ASSEMBLY LAYER STRUCTURE USED IN TOUCH CONTROL INTEGRATED CIRCUIT (IC) MODULE AND MANUFACTURING METHOD THEREOF

(71) Applicant: Lead-Honor Optronics Co., Ltd., Taoyuan County (TW)

(72) Inventors: Tsung-Sheng Chuang, Taoyuan County (TW); Chien-Le Lee, Taoyuan County (TW)

(21) Appl. No.: 15/169,550

(22) Filed: May 31, 2016

Related U.S. Application Data
(60) Provisional application No. 62/169,124, filed on Jun. 1, 2015.

(51) Int. Cl. H01L 23/31; G06K 9/00; G06F 3/041; H01L 23/29; H01L 21/56

(52) U.S. Cl. CPC H01L 23/3192; H01L 23/293; H01L 21/56; G06F 3/0416; G06K 9/00006

(57) ABSTRACT

An assembly layer structure applicable to a touch control integrated circuit (IC) module and manufacturing method thereof are described. The assembly layer structure comprises a substrate; a package layer, for being formed on the substrate; a color layer, for being formed on a upper surface of the package layer using a colorant in order to change color of the upper surface on the package layer; at least one intermediate layer, for connecting the color layer to a protection layer; and the protection layer, for being formed on the at least one intermediate layer wherein the protection layer is selected from one group consisting of epoxy resin, methyl methacrylate (MMA) and polyester resin.

### CROSS REFERENCE TO RELATED APPLICATION

This patent application claims priority of U.S. application Ser. No. 62/169,124, entitled “ASSEMBLY LAYER STRUCTURE USED IN A TOUCH CONTROL INTEGRATED CIRCUIT (IC) MODULE AND MANUFACTURING METHOD THEREOF”, which is filed on Jun. 1, 2015, incorporated herein by reference.

### BACKGROUND OF THE INVENTION

Field of Invention

The present invention relates to a structure used in an electronic apparatus and manufacturing method thereof, and more particularly to an assembly layer structure applicable to a touch control integrated circuit (IC) module, such as a fingerprint recognition chip, in the electronic apparatus and manufacturing method thereof to solve the problem of weak adhesion strength on the package layer's surface of the touch control IC.

Description of Prior Art

Due to the unique property and convenient use of fingerprint touch control integrated circuit (IC), the fingerprint recognition is widely used in the electronic apparatus. However, the conventional assembly layer structure applicable to a touch control integrated circuit (IC) module and manufacturing method thereof cannot easily change the color of the upper surface on the package layer and endure the pulling force of the assembly layer structure. Furthermore, the manufacturing processes of the assembly layer structure is quite complex. Consequently, there is a need to develop an assembly layer structure and manufacturing method thereof to solve the aforementioned problems.

### SUMMARY OF THE INVENTION

One objective of the present invention is to provide an assembly layer structure applicable to a touch control integrated circuit (IC) module and manufacturing method thereof in order to change the color of the upper surface of the package layer and enduring the pulling force of the assembly layer structure.

According to the above objective, the present invention sets forth an assembly layer structure applicable to a touch control IC module and manufacturing method thereof.

The assembly layer structure applicable to a touch control integrated circuit (IC) module comprises a substrate; a package layer, for being formed on the substrate; a color layer, for being formed on a upper surface of the package layer using a colorant in order to change color of the upper surface on the package layer; at least one intermediate layer disposed between the color layer and a protection layer, for connecting the color layer to the protection layer; and the protection layer, for being formed on the at least one intermediate layer wherein the protection layer is selected from one group consisting of epoxy resin, methyl methacrylate (MMA) and polyester resin.

In one embodiment, the package layer comprises a plurality of touch control ICs which are correspondingly encapsulated in a plurality of the recesses of the package layer respectively by encapsulation glue.

In one embodiment, the encapsulation glue and the at least one intermediate layer respectively are selected from one group consisting of epoxy, acrylate adhesive, polyurethane adhesive, styrene-butadiene-styrene (SBS) adhesive, and MMA, and the at least one intermediate layer is an adhesive layer for adhering the color layer to a protection layer.

In one embodiment, the colorant of the color layer is formed by a procedure selected from one group consisting of a printing ink procedure, a spraying coating procedure, a spin coating procedure, a rolling coating procedure and a hot-transfer printing procedure.

In one embodiment, a roughness, defined by arithmetical mean deviation, on a upper surface of the color layer and on a lower surface of the protection layer has a range from 0.001 to 5 micrometers.

In one embodiment, the roughness has the range from 0.01 to 0.5 micrometers.

In one embodiment, the at least one intermediate layer is an adhesive layer for adhering the color layer to a protection layer, and when the adhesive layer is coated on the color layer, the adhesive layer is capable of enduring the pulling force ranging from 10 to 40 kilograms per square centimeter, and the at least one intermediate layer is an adhesive layer for adhering the color layer to a protection layer.

In one embodiment, the protection layer is processed by either a thermal curing procedure or an ultraviolet (UV) light curing procedure for solidifying the material of epoxy resin, MMA, and polyester resin.

In one embodiment, the at least one intermediate layer is at least one adhesive layer for adhering the color layer to the protection layer and the at least one adhesive layer comprises: a first adhesive layer disposed between the package layer and the color layer, for adhering the package layer to the color layer; and a second adhesive layer disposed between the color layer and the protection layer, for adhering the color layer to the protection layer.

In one embodiment, the package layer and the color layer forms a composite layer which is a layer constructed by adding the colorant of the cooler layer to either an epoxy resin or MMA material of the package layer.

In one embodiment, either an organic or an inorganic colorant is mixed with either the epoxy resin or the MMA to construct the composite layer which has a thickness ranging from 0.3 to 200 micrometers.

In one embodiment, the at least one intermediate layer is at least one coating layer for connecting the color layer to the protection layer and the at least one coating layer comprises: a first coating layer disposed between the package layer and the color layer, for connecting the package layer to the color layer; and a second coating layer disposed between the color layer and the protection layer, for connecting the color layer to the protection layer.

In one embodiment, an assembly layer structure applicable to a touch control integrated circuit (IC) module comprises: a substrate; a composite layer which is a layer constructed by adding the colorant of the cooler layer to either an epoxy resin or MMA material of the package layer wherein the composite layer is formed on the substrate for connecting the substrate to a protection layer; a protection layer, for being formed on the composite layer wherein the protection layer is selected from one group consisting of epoxy resin, methyl methacrylate (MMA) and polyester resin.

In one embodiment, a method of forming an assembly layer structure applicable to a touch control integrated circuit (IC) module comprises the steps of: providing a substrate; forming a package layer on the substrate; forming a color layer on a upper surface of the package layer using a colorant in order to change color of the upper surface on the package layer; forming at least one intermediate layer disposed between the color layer and a protection layer for connecting the color layer to the protection layer; and forming the protection layer on the at least one intermediate layer wherein the protection layer is selected from one group consisting of epoxy resin, methyl methacrylate (MMA) and polyester resin.

In one embodiment, the colorant of the color layer is formed by a procedure selected from one group consisting of a printing ink procedure, a spraying coating procedure, a spin coating procedure, a rolling coating procedure and a hot-transfer printing procedure.

In one embodiment, a roughness, defined by arithmetical mean deviation, on a upper surface of the color layer and on a lower surface of the protection layer has a range from 0.001 to 5 micrometers.

In one embodiment, during the step of forming at least one intermediate layer disposed between the color layer and a protection layer for connecting the color layer to the protection layer, the at least one intermediate layer is an adhesive layer for adhering the color layer to a protection layer, and when the adhesive layer is coated on the color layer, the adhesive layer is capable of enduring the pulling force ranging from 10 to 40 kilograms per square centimeter, and the at least one intermediate layer is an adhesive layer for adhering the color layer to a protection layer.

In one embodiment, during the step of forming at least one intermediate layer disposed between the color layer and a protection layer for connecting the color layer to the protection layer, the at least one intermediate layer is at least one adhesive layer for adhering the color layer to the protection layer, further comprising the steps of: forming a first adhesive layer disposed between the package layer and the color layer, for adhering the package layer to the color layer; and forming a second adhesive layer disposed between the color layer and the protection layer, for adhering the color layer to the protection layer.

In one embodiment, the package layer and the color layer forms a composite layer which is a layer constructed by adding the colorant of the cooler layer to either an epoxy resin or MMA material of the package layer.

In one embodiment, the at least one intermediate layer is at least one coating layer for connecting the color layer to the protection layer, further comprising the steps of: forming a first coating layer disposed between the package layer and the color layer, for connecting the package layer to the color layer; and forming a second coating layer disposed between the color layer and the protection layer, for connecting the color layer to the protection layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic cross-sectional view of an assembly layer structure used in a touch control IC module according to a first embodiment of the present invention;

FIG. 2 is a schematic cross-sectional view of the assembly layer structure used in the touch control IC module according to a second embodiment of the present invention;

FIG. 3 is a schematic cross-sectional view of the assembly layer structure used in the touch control IC module according to a third embodiment of the present invention;

FIG. 4 is a schematic cross-sectional view of the assembly layer structure used in the touch control IC module according to a fourth embodiment of the present invention;

FIG. 5 is a schematic cross-sectional view of the assembly layer structure used in the touch control IC module according to a fifth embodiment of the present invention; and

FIG. 6 is a flow chart of a method of forming an assembly layer structure applicable to a touch control IC module according to one embodiment of the present invention.

### DETAILED DESCRIPTION OF THE PREFERRED EMBODIMENTS

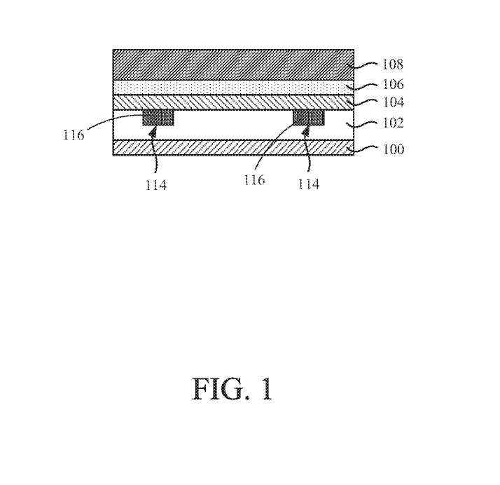

Refer to FIG. 1, which is a schematic cross-sectional view of an assembly layer structure used in a touch control IC module according to a first embodiment of the present invention. The assembly layer structure includes a substrate 100, a package layer 102, a color layer 104, an adhesive layer 106 and a protection layer 108. The package layer 102 is formed on the substrate 100, e.g. a printed circuit board (PCB) and/or a flexible printed circuit (FPC). The package layer 102 includes a plurality of touch control ICs 116 which are encapsulated in the recesses 114 of the package layer 102 respectively by encapsulation glue, wherein the encapsulation glue is composed of one or a combination of the epoxy, acrylate adhesives, polyurethane adhesives, styrene-butadiene-styrene (SBS) adhesives, and methyl methacrylate (MMA). The color layer 104 is formed on the upper surface of the package layer 102 and/or touch control ICs 116 using a colorant by printing ink, spraying coating, spin coating, rolling coating and/or hot-transfer printing procedure in order to change the color of the upper surface of the package layer 102 and/or touch control ICs 116.

In FIG. 1, the adhesive layer 106 adhered between the color layer 104 and the protection layer 108 includes one or an integration of the epoxy adhesives, acrylate adhesives, polyurethane adhesives, SBS adhesives, and MMA for fastening the color layer 104 to the protection layer 108 and/or touch control ICs 116. In details, the roughness, e.g. the indication Ra (defined by arithmetical mean deviation), on the upper surface of the color layer 104 and on the lower surface of the protection layer 108 has the range from 0.001 to 5 micrometers, preferably from 0.01 to 0.5 micrometers. In some cases, the roughness of the upper surface of the color layer 104 is different from or the same as the roughness of the lower surface of the protection layer 108. In one embodiment, the hardness, e.g. the pencil hardness defined by manufacturer Mitsubishi, of the adhesive layer 106 has the range from “3B” to “2H” when the loading from 100 to 1000 grams, preferably 500 grams is applied to the adhesive layer 106. In one embodiment, the adhesive layer 106 is adhered to the protection layer 108 and/or touch control ICs 116 and the color layer 104 therebetween by the chemical bonding on condition that the pressure from 20 to 50 kilograms per square centimeter and the temperature from 30 to 250 degrees Celsius, preferably from 90 to 160 degrees Celsius, are exerted on the adhesive layer 106. When the adhesive layer 106 is coated on the color layer 104, the adhesive layer 106 is capable of enduring the pulling force ranging from 10 to 40 kilograms per square centimeter, preferably from 20 to 40 kg/cm², such that the protection layer 108 on the adhesive layer 106 thus meets the requirement of adhesive tape No. 600 defined by manufacturer 3M in an adhesion test procedure.

As shown in FIG. 1, the protection layer 108 formed on the adhesive layer 106 includes one or integration of the material composed of epoxy resin, MMA, and polyester resin. In one embodiment, the protection layer 108 is processed by thermal curing and/or ultraviolet (UV) light curing procedure for solidifying the material of epoxy resin, MMA, and/or polyester resin so that the surface of the protection layer 108 has the visual effects of mirror-polished, anti-glare and/or customization pattern for good hardness, optimum scratch resistance and easy clean.

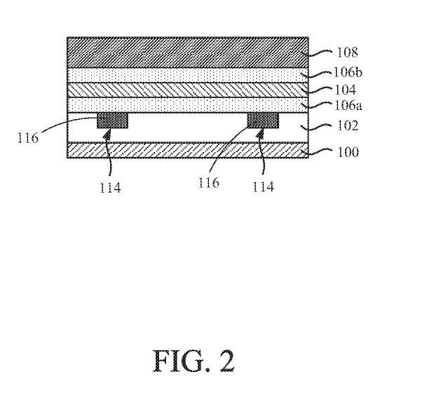

Refer to FIG. 2, which is a schematic cross-sectional view of the assembly layer structure used in the touch control IC module according to a second embodiment of the present invention. The assembly layer structure includes a substrate 100, a package layer 102, a first adhesive layer 106a, a color layer 104, a second adhesive layer 106b and a protection layer 108. The package layer 102 is formed on the substrate 100, e.g. PCB and/or FPC. The package layer 102 includes a plurality of touch control ICs 116 which are correspondingly encapsulated in the recesses 114 of the package layer 102 by the encapsulation glue, wherein the encapsulation glue is composed of one or combination of the epoxy, acrylate adhesives, polyurethane adhesives, SBS adhesives, and MMA.

In FIG. 2, the first adhesive layer 106a adhered between package layer 102, the color layer 104 and/or touch control ICs 116 includes one or integration of the epoxy adhesives, acrylate adhesives, polyurethane adhesives, SBS adhesives, and MMA for fastening the package layer 102 and/or touch control ICs 116 to the color layer 104. In details, the roughness, e.g. the indication Ra (defined by arithmetical mean deviation), on the upper surface of the package layer 102 and on the lower surface of the color layer 104 has the range from 0.001 to 5 micrometers, preferably from 0.01 to 0.5 micrometers. In some cases, the roughness of the upper surface of the package layer 102 is different from or the same as the roughness of the lower surface of the color layer 104. In one embodiment, the hardness, e.g. the pencil hardness defined by manufacturer Mitsubishi, of the first adhesive layer 106a has the range from “3B” to “2H” when the loading from 100 to 1000 grams, preferably 500 grams is applied to the first adhesive layer 106a. In one embodiment, the first adhesive layer 106a is adhered to the package layer 102 and/or touch control ICs 116 and the color layer 104 therebetween by the chemical bonding on condition that the pressure from 20 to 50 kilograms per square centimeter and the temperature from 30 to 250 degrees Celsius, preferably from 90 to 160 degrees Celsius, are exerted on the first adhesive layer 106a. When the first adhesive layer 106a is coated on the package layer 102 and/or touch control ICs 116, the first adhesive layer 106a is capable of enduring the pulling force ranging from 20 to 40 kilograms per square centimeter, preferably from 20 to 40 kg/cm², such that the color layer 104 on the first adhesive layer 106a thus meets the requirement of adhesive tape No. 600 defined by manufacturer 3M in an adhesion test procedure.

In FIG. 2, the color layer 104 is formed on the upper surface of the first adhesive layer 106a using a colorant by printing ink, spraying coating, spin coating, rolling coating and/or hot-transfer printing procedure in order to change the color of the upper surface of package layer 102, the first adhesive layer 106a, and/or touch control ICs 116.

In FIG. 2, the second adhesive layer 106b adhered between the color layer 104 and the protection layer 108 includes one or integration of the epoxy adhesives, acrylate adhesives, polyurethane adhesives, SBS adhesives, and MMA. In one embodiment, the roughness, e.g. the indication Ra (arithmetical mean deviation), of the upper surface of the color layer 104 and the lower surface of the protection layer 108 has the range from 0.001 to 5 micrometers, preferably from 0.01 to 0.5 micrometers. In some cases, the roughness of the upper surface of the color layer 104 is different from or the same as the roughness of the lower surface of the protection layer 108. In one embodiment, the hardness, e.g. the pencil hardness defined by manufacturer Mitsubishi, of the second adhesive layer 106b has the range from “3B” to “2H” when the loading from 100 to 1000 grams, preferably 500 grams is applied to the second adhesive layer 106b. The second adhesive layer 106b is adhered to the protection layer 108 and the color layer 104 therebetween by the chemical bonding on condition that the pressure from 20 to 50 kilograms per square centimeter and the temperature from 30 to 250 degrees Celsius, preferably from 90 to 160 degrees Celsius, are exerted on the second adhesive layer 106b. When the second adhesive layer 106b is coated on the color layer 104, the second adhesive layer 106b is capable of enduring the pulling force ranging from 20 to 40 kilograms per square centimeter, preferably from 20 to 40 kg/cm², such that the protection layer 108 on the second adhesive layer 106b thus meets the requirement of adhesive tape No. 600 defined by manufacturer 3M in an adhesion test procedure.

As shown in FIG. 2, the protection layer 108 formed on the second adhesive layer 106b includes one or integration of the material composed of epoxy resin, MMA, and polyester resin. In one embodiment, the protection layer 108 is processed by thermal curing and/or ultraviolet (UV) light curing procedure for solidifying the material of epoxy resin, MMA, and/or polyester resin so that the surface of the protection layer 108 has the visual effects of mirror-polished, anti-glare or customization pattern for good hardness, optimum scratch resistance and easy clean.

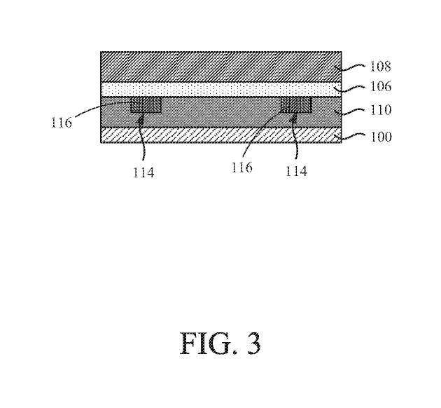

Refer to FIG. 3, which is a schematic cross-sectional view of the assembly layer structure used in the touch control IC module according to a third embodiment of the present invention. The assembly layer structure includes a substrate 100, a composite layer 110, an adhesive layer 106 and a protection layer 108. The substrate 100 has a thickness ranging from 0.1 to 100 micrometers, preferably from 1 to 5 micrometers.

In FIG. 3, the composite layer 110 is a layer formed by adding colorant to an epoxy resin or MMA material. For example, the organic and/or inorganic colorant is mixed with the epoxy resin or MMA to form the composite layer 110 which has a thickness ranging from 0.3 to 200 micrometers, preferably from 3 to 20 micrometers. The composite layer 110 is formed on the substrate 100, e.g. PCB and/or FPC. The composite layer 110 includes a plurality of touch control ICs 116 which are respectively encapsulated in the recesses 114 of the composite layer 110 by encapsulation glue, wherein the encapsulation glue is composed of one or combination of the epoxy, acrylate adhesives, polyurethane adhesives, SBS adhesives, and MMA. The light transmittance of the composite layer 110 has the range from 0% to 98% depending on the quantity of the added colorant. Furthermore, the composite layer 110 is formed on the upper surface of the substrate 100 by printing ink, spraying coating, spin coating, rolling coating and hot-transfer printing procedures at the pre-heated temperature from 50 to 120 degrees Celsius, preferably 80 degrees Celsius, for 15 minutes and the UV light energy is applied from 600 to 800 mj/cm² in the wavelength 365 nm for solidifying the composite layer 110.

As shown in FIG. 3, the adhesive layer 106 is the same as that in FIG. 1 and is formed on the composite layer 110 by one or integration of the epoxy, acrylate adhesives, polyurethane adhesives, SBS adhesives, and MMA. The protection layer 108 formed on the adhesive layer 106 includes one or integration of the material composed of epoxy resin, MMA, polyester resin with organic and/or inorganic components. The protection layer 108 has a thickness from 0.3 to 300 micrometers, preferably from 3 to 30 micrometers. In one embodiment, the protection layer 108 is formed by thermal curing and/or UV light curing procedure for solidifying the material of epoxy resin, MMA, and polyester resin so that the surface of the protection has the visual effects of mirror-polished, anti-glare or customization pattern for good hardness, optimum scratch resistance and easy clean.

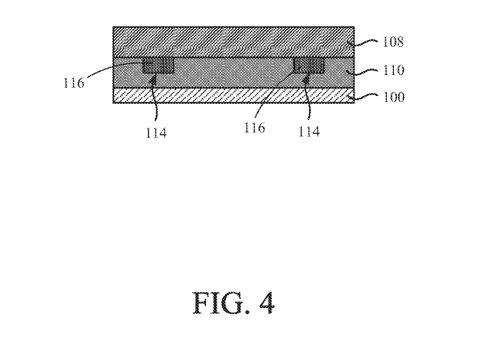

Refer to FIG. 4, which is a schematic cross-sectional view of the assembly layer structure used in the touch control IC module according to a fourth embodiment of the present invention. The assembly layer structure includes a substrate 100, a composite layer 110 and a protection layer 108. The substrate 100 has thickness ranging from 0.1 to 100 micrometers, preferably from 1 to 5 micrometers.

In FIG. 4, the composite layer 110, which is the same as that in FIG. 3, is a layer formed by adding colorant to an epoxy resin or MMA. For example, the organic and/or inorganic colorant is mixed with the epoxy resin or MMA to form the composite layer 110 which has a thickness ranging from 0.3 to 200 micrometers, preferably from 3 to 20 micrometers. The composite layer 110 is formed on the substrate 100, e.g. PCB and/or FPC. In one embodiment, the composite layer 110 includes a plurality of touch control ICs 116 which are respectively encapsulated in the recesses 114 of the composite layer 110 by encapsulation glue, wherein the encapsulation glue is composed of one or combination of the epoxy, acrylate adhesives, polyurethane adhesives, SBS adhesives, and MMA. The light transmittance of the composite layer 110 has the range from 0% to 98% depending on the quantity of the added colorant. Furthermore, the composite layer 110 is formed on the upper surface of the substrate 100 by printing ink, spraying coating, spin coating, rolling coating and hot-transfer printing procedures at the pre-heated temperature from 50 to 120 degrees Celsius, preferably 80 degrees Celsius, for 15 minutes and the UV light energy is applied from 600 to 800 mj/cm² in the wavelength 365 nm for solidifying the composite layer 110.

In FIG. 4, the protection layer 108 is adhered to the composite layer 110. The protection layer 108 includes one or integration of the material composed of epoxy resin, MMA, polyester resin with organic and/or inorganic components. The protection layer 108 has a thickness from 0.3 to 300 micrometers, preferably from 3 to 30 micrometers. In one embodiment, the protection layer 108 is formed by thermal curing and/or UV light curing procedure for solidifying the material of epoxy resin, MMA, polyester resin so that the surface of the protection has the visual effects of mirror-polished, anti-glare and customization pattern for good hardness, optimum scratch resistance and easy clean.

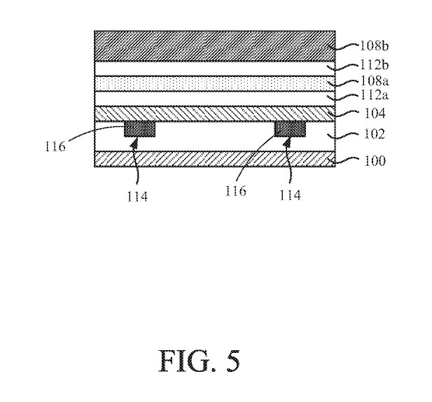

Refer to FIG. 5, which is a schematic cross-sectional view of the assembly layer structure used in the touch control IC module according to a fifth embodiment of the present invention. The assembly layer structure includes a substrate 100, a package layer 102, a color layer 104, a first coating layer 112a, a protection layer 108a, and a second coating layer 112b. The package layer 102 is formed on the substrate 100, e.g. PCB and/or FPC. The package layer 102 includes a plurality of touch control ICs 116 which are encapsulated in the recesses 114 of the package layer 102 by encapsulation glues, e.g. one or integration of the epoxy, acrylate adhesives, polyurethane adhesives, SBS adhesives, and MMA.

In FIG. 5, the first coating layer 112a, e.g. physical vapor deposition (PVD) coating, with light transmittance 99% is formed on the color layer 104. The first coating layer 112a is composed of higher refractive index or lower refractive index, such as TiO₂, SiO₂, NbO₂, FMg₂ formed by a PVD process to increase the metallic feel or quality, or predetermined colors, e.g. blue color, purple red color by interference scheme. The protection layer 108a formed on the first coating layer 112a includes one or integration of the material composed of epoxy resin, MMA, polyester resin. In one embodiment, the protection layer 108a is formed by thermal curing and/or UV curing for solidifying the material of epoxy resin, MMA, polyester resin so that the surface of the protection has the visual effects of mirror-polished, anti-glare or customization pattern for good hardness, optimum scratch resistance and easy clean. The second coating layer 112b is formed on the protection layer 108a to increase the strength and hardness of assembly layer structure. In one embodiment, the material of the second coating layer 112b is different from or the same as the material of the first coating layer 112a. In one embodiment, another protection layer 108b is selectively formed on the second coating layer 112b.

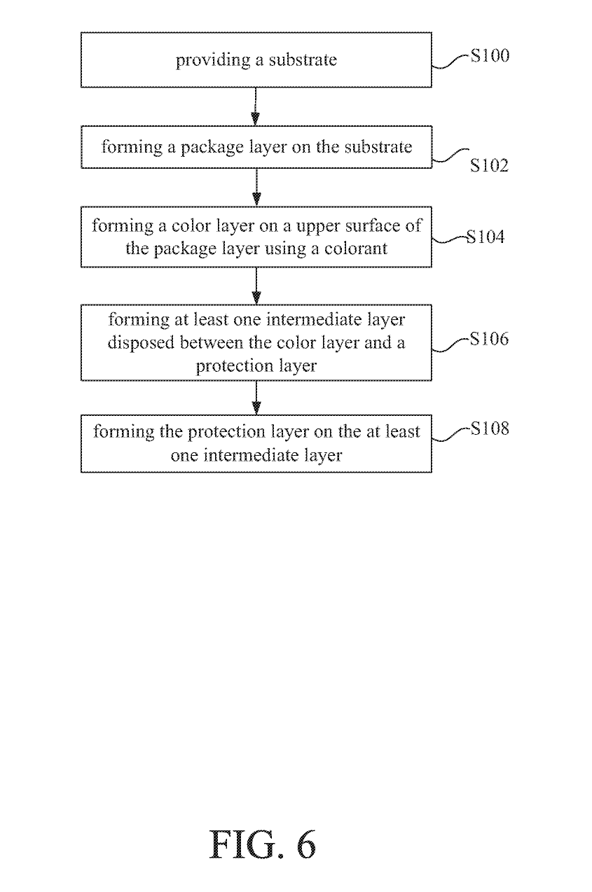

Refer to FIG. 6, which is a flow chart of a method of forming an assembly layer structure applicable to a touch control IC module according to one embodiment of the present invention. The method includes the following steps.

In step S100, a substrate is provided.

In step S102, a package layer on the substrate is formed.

In step S104, a color layer is formed on a upper surface of the package layer using a colorant in order to change color of the upper surface of the package layer.

In step S106, at least one intermediate layer disposed between the color layer and a protection layer is formed for connecting the color layer to the protection layer.

In step S108, the protection layer is formed on the at least one intermediate layer wherein the protection layer is selected from one group consisting of epoxy resin, MMA and polyester resin.

According to the above-mentioned descriptions, the present invention provides an assembly layer structure applicable to a touch control integrated circuit (IC) module and manufacturing method thereof in order to change the color of the upper surface of the package layer and enduring the pulling force of the assembly layer structure.

As is understood by a person skilled in the art, the foregoing preferred embodiments of the present invention are illustrative rather than limiting of the present invention. It is intended that they cover various modifications and similar arrangements be included within the spirit and scope of the present invention, the scope of which should be accorded the broadest interpretation so as to encompass all such modifications and similar structure.

What is claimed is:

1. An assembly layer structure applicable to a touch control integrated circuit (IC) module, the assembly layer structure comprising:
a substrate;
a package layer, for being formed on the substrate;
a color layer, for being formed on a upper surface of the package layer using a colorant in order to change color of the upper surface of the package layer;
at least one intermediate layer disposed between the color layer and a protection layer, for connecting the color layer to the protection layer; and
the protection layer, for being formed on the at least one intermediate layer wherein the protection layer is selected from one group consisting of epoxy resin, methyl methacrylate (MMA) and polyester resin.

2. The assembly layer structure of claim 1, wherein the package layer comprises a plurality of touch control ICs which are correspondingly encapsulated in a plurality of recesses of the package layer respectively by encapsulation glue.

3. The assembly layer structure of claim 2, wherein the encapsulation glue and the at least one intermediate layer respectively are selected from one group consisting of epoxy, acrylate adhesive, polyurethane adhesive, styrene-butadiene-styrene (SBS) adhesive, and MMA, and the at least one intermediate layer is an adhesive layer for adhering the color layer to the protection layer.

4. The assembly layer structure of claim 1, wherein the colorant of the color layer is formed by a procedure selected from one group consisting of a printing ink procedure, a spraying coating procedure, a spin coating procedure, a rolling coating procedure and a hot-transfer printing procedure.

5. The assembly layer structure of claim 1, wherein a roughness, defined by arithmetical mean deviation, on a upper surface of the color layer and on a lower surface of the protection layer has a range from 0.001 to 5 micrometers.

6. The assembly layer structure of claim 5, wherein the roughness has the range from 0.01 to 0.5 micrometers.

7. The assembly layer structure of claim 1, wherein the at least one intermediate layer is an adhesive layer for adhering the color layer to a protection layer, and when the adhesive layer is coated on the color layer, the adhesive layer is capable of enduring the pulling force ranging from 10 to 40 kilograms per square centimeter, and the at least one intermediate layer is an adhesive layer for adhering the color layer to a protection layer.

8. The assembly layer structure of claim 1, wherein the protection layer is processed by either a thermal curing procedure or an ultraviolet (UV) light curing procedure for solidifying the material of epoxy resin, MMA, and polyester resin.

9. The assembly layer structure of claim 1, wherein the at least one intermediate layer is at least one adhesive layer for adhering the color layer to the protection layer and the at least one adhesive layer comprises:
a first adhesive layer disposed between the package layer and the color layer, for adhering the package layer to the color layer; and
a second adhesive layer disposed between the color layer and the protection layer, for adhering the color layer to the protection layer.

10. The assembly layer structure of claim 1, wherein the package layer and the color layer forms a composite layer which is a layer constructed by adding the colorant of the cooler layer to either an epoxy resin or MMA material of the package layer.

11. The assembly layer structure of claim 10, wherein either an organic or an inorganic colorant is mixed with either the epoxy resin or the MMA to construct the composite layer which has a thickness ranging from 0.3 to 200 micrometers.

12. The assembly layer structure of claim 1, wherein the at least one intermediate layer comprises:
a first coating layer disposed between the package layer and the color layer, for connecting the package layer to the color layer; and
a second coating layer disposed between the color layer and the protection layer, for connecting the color layer to the protection layer.

13. An assembly layer structure applicable to a touch control IC module, the assembly layer structure comprising:
a substrate;
a composite layer which is a layer constructed by adding the colorant of the cooler layer to either an epoxy resin or MMA material of the package layer wherein the composite layer is formed on the substrate for connecting the substrate to a protection layer; and
the protection layer, for being formed on the composite layer wherein the protection layer is selected from one group consisting of epoxy resin, MMA and polyester resin.

14. A method of forming an assembly layer structure applicable to a touch control IC module, the method comprising the steps of:
providing a substrate;
forming a package layer on the substrate;
forming a color layer on a upper surface of the package layer using a colorant in order to change color of the upper surface of the package layer;
forming at least one intermediate layer disposed between the color layer and a protection layer for connecting the color layer to the protection layer; and
forming the protection layer on the at least one intermediate layer wherein the protection layer is selected from one group consisting of epoxy resin, MMA and polyester resin.

15. The method of forming the assembly layer structure of claim 14, wherein the colorant of the color layer is formed by a procedure selected from one group consisting of a printing ink procedure, a spraying coating procedure, a spin coating procedure, a rolling coating procedure and a hot-transfer printing procedure.

16. The method of forming the assembly layer structure of claim 14, wherein a roughness, defined by arithmetical mean deviation, on a upper surface of the color layer and on a lower surface of the protection layer has a range from 0.001 to 5 micrometers.

17. The method of forming of the assembly layer structure of claim 14, wherein during the step of forming at least one intermediate layer disposed between the color layer and a protection layer for connecting the color layer to the protection layer, the at least one intermediate layer is an adhesive layer for adhering the color layer to a protection layer, and when the adhesive layer is coated on the color layer, the adhesive layer is capable of enduring the pulling force ranging from 10 to 40 kilograms per square centimeter, and the at least one intermediate layer is an adhesive layer for adhering the color layer to a protection layer.

18. The method of forming of the assembly layer structure of claim 14, wherein during the step of forming at least one intermediate layer disposed between the color layer and a protection layer for connecting the color layer to the protection layer, the at least one intermediate layer is at least one adhesive layer for adhering the color layer to the protection layer, further comprising the steps of:
forming a first adhesive layer disposed between the package layer and the color layer, for adhering the package layer to the color layer; and
forming a second adhesive layer disposed between the color layer and the protection layer, for adhering the color layer to the protection layer.

19. The method of forming the assembly layer structure of claim 14, wherein the package layer and the color layer forms a composite layer which is a layer constructed by adding the colorant of the cooler layer to either an epoxy resin or MMA material of the package layer.

20. The method of forming the assembly layer structure of claim 14, wherein during the step of forming at least one intermediate layer disposed between the color layer and a protection layer for connecting the color layer to the protection layer, the at least one intermediate layer is at least one coating layer for connecting the color layer to the protection layer, further comprising the steps of:
a first coating layer disposed between the package layer and the color layer, for connecting the package layer to the color layer; and
a second coating layer disposed between the color layer and the protection layer, for connecting the color layer to the protection layer.
